(19) United States
(12) Patent Application Publication
(10) Pub. No.: US 2026/0286195 A1
(43) Pub. Date: Sep. 24, 2026

(54) CURABLE RESIN COMPOSITION, CURABLE FILM, AND LAYERED FILM

(71) Applicant: Resonac Corporation, Tokyo (JP)

(72) Inventors: Yohei OHKODA, Tokyo (JP); Takashi KAWAMORI, Tokyo (JP); Takeshi MASAKI, Tokyo (JP); Kazuhiko MORI, Tokyo (JP); Shigeru KURIMOTO, Tokyo (JP)

(21) Appl. No.: 19/479,417

(22) PCT Filed: Jul. 3, 2024
(86) PCT No.: PCT/JP2024/024114

§ 371 Date: Oct. 28, 2025

(30) Foreign Application Priority Data
Jul. 6, 2023 (JP) 2023-111360

(51) Int. Cl. C09J 7/38; C09J 11/04

(52) U.S. Cl. CPC C09J 7/387; C09J 11/04; C09J 2203/326

(57) ABSTRACT

A curable resin composition according to an aspect of the present disclosure contains (A) a rubber component, (B) a compound having an epoxy group, (C) a curing agent, (D) a curing accelerator, and (E) a filler, in which the (A) rubber component includes a modified styrene-based elastomer having a modification ratio of maleic anhydride of 1.8% to 10.0% by mass.

### TECHNICAL FIELD

The present disclosure relates to a curable resin composition, a curable film, and a layered film.

### BACKGROUND ART

In recent years, as the speed of transmitted signals on printed wiring boards increases, the frequency of signals is becoming increasingly higher. Along with this, there is an increasing demand for printed wiring boards to have low dielectric characteristics (low dielectric constant and low dielectric loss tangent) in the high frequency range. Furthermore, protective layers (coverlays) that cover the circuits of printed wiring boards, interlayer adhesives in multilayer printed wiring boards, and the like are also required to have low dielectric characteristics in addition to having adhesiveness to substrates and the like. As a resin composition that can give a cured product having low dielectric characteristics, for example, Patent Literature 1 proposes an adhesive composition containing a styrene-based elastomer.

### CITATION LIST

### Patent Literature

Patent Literature 1: JP 2018-150543 A

### SUMMARY OF INVENTION

### Technical Problem

The above-described adhesive composition that uses an elastomer tends to easily give a cured product having excellent dielectric characteristics; however, the adhesive composition may be required to sufficiently embed, when used as an interlayer adhesive or the like, a circuit of a printed wiring board within the cured product.

The present disclosure was achieved in view of the above-described circumstances, and it is an object of the present disclosure to provide a curable resin composition having excellent embedding properties, a curable film, and a layered film.

### Solution to Problem

In order to solve the above-described problems, the present disclosure provides the following curable resin composition, curable film, and layered film.
[1] A curable resin composition comprising (A) a rubber component, (B) a compound having an epoxy group, (C) a curing agent, (D) a curing accelerator, and (E) a filler, wherein the (A) rubber component includes a modified styrene-based elastomer having a modification ratio of maleic anhydride of 1.8% to 10.0% by mass.
[2] The curable resin composition according to the above-described item [1], wherein the curable resin composition is used as an interlayer adhesive for a multilayer printed wiring board.
[3] The curable resin composition according to the above-described item [1] or [2], wherein the modified styrene-based elastomer has a weight average molecular weight of 20000 to 120000.
[4] The curable resin composition according to any one of the above-described items [1] to [3], wherein the (B) compound having an epoxy group has a weight average molecular weight of 200 to 1000.
[5] The curable resin composition according to any one of the above-described items [1] to [4], wherein a content of the (D) curing accelerator is 0.1 to 10 parts by mass with respect to 100 parts by mass of a total amount of the (A) rubber component, the (B) compound having an epoxy group, and the (C) curing agent.
[6] The curable resin composition according to any one of the above-described items [1] to [5], wherein the (E) filler includes a surface-treated filler.
[7] The curable resin composition according to the above-described item [6], wherein the surface-treated filler includes a filler having at least one group selected from the group consisting of an epoxy group, a vinyl group, and a phenylamino group.
[8] A curable film comprising the curable resin composition according to any one of the above-described items [1] to [7].
[9] A layered film including:
a substrate film; and
the curable film according to the above-described item [8] provided on the substrate film.

### Advantageous Effects of Invention

According to the present disclosure, a curable resin composition having excellent embedding properties, a curable film, and a layered film can be provided.

### DESCRIPTION OF EMBODIMENTS

Hereinafter, several embodiments of the present disclosure will be described in detail. However, the present disclosure is not limited to the following embodiments.

In the present specification, a numerical value range indicated using the term “to” indicates a range including the numerical values described before and after the term “to” as the minimum value and the maximum value, respectively. With regard to a numerical value range described stepwise in the present specification, the upper limit value or lower limit value of the numerical value range of a certain stage may be arbitrarily combined with the upper limit value or lower limit value of the numerical value range of another stage. Furthermore, with regard to a numerical value range described in the present specification, the upper limit value or lower limit value of the numerical value range may be replaced with a value shown in the Examples. In a case where the amount of each component in a composition is mentioned in the present specification, when there are a plurality of substances corresponding to each component in the composition, unless particularly stated otherwise, the amount means the total amount of the plurality of substances present in the composition. Regarding the phrase “A or B”, either A or B may be included, or both of them may be included. The term “solid content” refers to a non-volatile fraction excluding volatile substances (water, solvent, and the like) in the resin composition. That is, the “solid content” refers to components other than the solvent that remains without volatilizing when the resin composition that will be described below is dried, and the “solid content” also includes components that are liquid, syrup-like, or wax-like at room temperature (25° C.). In the present specification, for example, the expression “(meth)acrylic acid” means “acrylic acid” and “methacrylic acid” corresponding thereto, and the same also applies to other similar words.

### [Curable Resin Composition]

A curable resin composition according to the present embodiment contains (A) a rubber component, (B) a compound having an epoxy group, (C) a curing agent, (D) a curing accelerator, and (E) a filler, and the (A) rubber component includes a modified styrene-based elastomer having a modification ratio of maleic anhydride of 1.8% to 10.0% by mass.

The curable resin composition according to the present embodiment can be used for forming a protective layer (coverlay) that covers an electric circuit on a printed wiring board, or as an interlayer adhesive or the like in a multilayer printed wiring board. The curable resin composition according to the present embodiment has adhesiveness to adherends, for example, a metal portion of a printed wiring board, and materials constituting a printed wiring board such as a substrate, and by using a modified styrene-based elastomer having a modification ratio of maleic anhydride of 1.8% to 10.0% by mass as a rubber component, the curable resin composition can sufficiently embed a circuit of a printed wiring board when used as an interlayer adhesive. Hereinafter, each component that may be included in the curable resin composition will be described.

### <(A) Rubber Component>

When the (A) rubber component includes a modified styrene-based elastomer having a modification ratio of maleic anhydride of 1.8% to 10.0% by mass (hereinafter, referred to as “modified styrene-based elastomer (A1)”), the compatibility with other components (in particular, (B) a compound having an epoxy group) is increased, and the embedding properties of the curable resin composition can be improved. When the modified styrene-based elastomer (A1) has an acid anhydride group derived from maleic anhydride, the strength, heat resistance, and adhesiveness of the cured product tend to be easily improved.

The modified styrene-based elastomer (A1) can be produced by reacting a styrene-based elastomer with maleic anhydride and has an acid anhydride group based on maleic anhydride in a side chain. The styrene-based elastomer may be a copolymer having a structural unit derived from a styrene-based compound and a structural unit derived from a conjugated diene compound.

Examples of the styrene-based compound include styrene, α-methylstyrene, p-methylstyrene, and p-tert-butylstyrene. Among these, from the viewpoints of availability and productivity, styrene, x-methylstyrene, and 4-methylstyrene are preferred, and styrene is more preferred.

Examples of the conjugated diene compound include 1,3-butadiene, 2-methyl-1,3-butadiene (isoprene), 1,3-pentadiene (piperylene), 1-phenyl-1,3-butadiene, 2,3-dimethyl-1,3-butadiene, 2-methyl-1,3-pentadiene, 3,4-dimethyl-1,3-hexadiene, and 4,5-diethyl-1,3-octadiene. Among these, from the viewpoints of availability and productivity, 1,3-butadiene and isoprene are preferred.

The styrene-based elastomer may be a hydrogenated styrene-based elastomer in which at least a portion of the structural units derived from a conjugated diene compound is hydrogenated. Examples of the hydrogenated styrene-based elastomer include a hydrogenated product of a styrene-butadiene-styrene block copolymer (styrene ethylene butylene styrene elastomer, SEBS) and a hydrogenated product of a styrene-isoprene-styrene block copolymer. Examples of a commercially available product of SEBS include TUFTEC (registered trademark) H series manufactured by Asahi Kasei Corporation, SEPTON (registered trademark) series manufactured by Kuraray Co., Ltd., and KRATON (registered trademark) G POLYMER Series manufactured by Kraton Polymers Japan, Ltd.

From the viewpoint of further enhancing the compatibility with other components, the modification ratio of maleic anhydride of the modified styrene-based elastomer (A1) may be 1.8% by mass or more, 1.9% by mass or more, or 2.0% by mass or more. From the viewpoint of improving the dielectric characteristics, the modification ratio of maleic anhydride may be 9.0% by mass or less, 8.0% by mass or less, 7.0% by mass or less, or 6.0% by mass or less. The above-described modification ratio may be 1.8% to 9.0% by mass, 1.8% to 8.0% by mass, 1.9% to 7.0% by mass, or 2.0% to 6.0% by mass. The modification ratio can be calculated using the acid value of the modified styrene-based elastomer.

From the viewpoint of further enhancing compatibility, the acid value of the modified styrene-based elastomer (A1) may be 20 to 120 mg KOH/g, 25 to 100 mg KOH/g, 30 to 90 mg KOH/g, or 35 to 80 mg KOH/g.

From the viewpoints of coating film properties and circuit embedding properties, the weight average molecular weight (Mw) of the modified styrene-based elastomer (A1) may be 20000 to 120000, 30000 to 110000, 40000 to 100000, or 50000 to 80000. The Mw means a value determined by gel permeation chromatography (GPC) and calculated relative to polystyrene standards.

The content of the modified styrene-based elastomer (A1) is preferably 10% to 95% by mass, more preferably 15% to 90% by mass, and even more preferably 20% to 85% by mass, based on the total amount of the (A) rubber component, the (B) compound having an epoxy group, and the (C) curing agent. When the content of (A1) is 10% by mass or more, the embedding properties tend to be more excellent. When the content of (A1) is 95% by mass or less, the resulting cured product tends to have particularly excellent characteristics in terms of adhesiveness, connection reliability, and insulation reliability. Incidentally, the content of (A1) in the cured product may be within the above-described range based on the mass of the cured product.

The (A) rubber component may further include a modified styrene-based elastomer having modification ratio of maleic anhydride of less than 1.8% by mass (hereinafter, referred to as “modified styrene-based elastomer (A2)”). Examples of a commercially available product of the modified styrene-based elastomer (A2) include “FG1901” and “FG1924” from Kraton Polymers Japan, Ltd., and “TUFTEC M1911”, “TUFTEC M1913”, and “TUFTEC M1943” from Asahi Kasei Corporation.

The (A) rubber component may further include an unmodified rubber component that is not modified with maleic anhydride. Examples of the unmodified rubber component include acrylic rubber, isoprene rubber, butyl rubber, styrene butadiene rubber, butadiene rubber, styrene butylene styrene rubber, styrene ethylene propylene styrene rubber, styrene ethylene butylene styrene rubber, acrylonitrile butadiene rubber, silicone rubber, urethane rubber, chloroprene rubber, ethylene propylene rubber, fluororubber, vulcanized rubber, epichlorohydrin rubber, and chlorinated butyl rubber.

Examples of a commercially available product of acrylic rubber include “Nipol AR Series” from Zeon Corporation, and “KURARITY Series” from Kuraray Co., Ltd. Examples of a commercially available product of isoprene rubber include “Nipol IR Series” from Zeon Corporation. Examples of a commercially available product of butadiene rubber include “Nipol BR Series” from Zeon Corporation. Examples of a commercially available product of acrylonitrile butadiene rubber include “NBR Series” from ENEOS Materials Corporation. Examples of a commercially available product of silicone rubber include “KMP Series” from Shin-Etsu Silicone Co., Ltd. Examples of a commercially available product of ethylene propylene rubber include “EP Series” from ENEOS Materials Corporation. Examples of a commercially available product of fluororubber include “DAI-EL Series” from Daikin Industries, Ltd. Examples of a commercially available product of epichlorohydrin rubber include “Hydrin Series” from Zeon Corporation.

In the curable resin composition, the content of the (A) rubber component may be 50% to 95% by mass, 65% to 90% by mass, or 60% to 85% by mass, based on the total amount of the (A) rubber component, the (B) compound having an epoxy group, and the (C) curing agent. When the content of the (A) rubber component is 50% by mass or more, the (A) rubber component tends to be more highly compatible with other components, and the dielectric characteristics of the resulting cured product tend to be excellent. When the content of the (A) rubber component is 95% by mass or less, the resulting cured product tends to have particularly excellent characteristics in terms of adhesiveness, connection reliability, insulation reliability, and heat resistance. The content of the (A) rubber component in the cured product may be within the above-described range based on the mass of the cured product.

### <(B) Compound Having Epoxy Group>

The (B) compound having an epoxy group is not particularly limited as long as it has an epoxy group in the molecule, and the compound may be, for example, a common epoxy resin. The epoxy resin may be any of monofunctional, bifunctional, or polyfunctional (trifunctional or higher-functional) and is not particularly limited; however, from the viewpoint of further obtaining curability, a bifunctional or polyfunctional epoxy resin may be used.

Examples of the epoxy resin include epoxy resins of bisphenol A type, bisphenol F type, phenol novolac type, naphthalene type, dicyclopentadiene type, and cresol novolac type. From the viewpoints of low tackiness, dielectric characteristics, and heat resistance, a naphthalene type or dicyclopentadiene type epoxy resin may be selected as the (B) compound having an epoxy group, or a dicyclopentadiene type epoxy resin may be selected. These epoxy resins can be used singly or in combination of two or more kinds thereof.

By using a combination of a rubber having a maleic anhydride group or a carboxy group and a compound having an epoxy group (epoxy resin), particularly excellent effects in terms of the heat resistance, low moisture permeability, and adhesiveness of the cured product tend to be obtained. When the heat resistance of the cured product is improved, for example, deterioration of the cured product in a heating step such as nitrogen reflow can be suppressed.

The weight average molecular weight (Mw) of the (B) compound having an epoxy group may be, for example, 200 to 2000; however, from the viewpoints of the fluidity of the resin composition and the dielectric characteristics of the cured product, the weight average molecular weight (Mw) is preferably 200 to 1000, more preferably 250 to 800, even more preferably 300 to 550, and particularly preferably 350 to 450.

The number average molecular weight (Mn) of the (B) compound having an epoxy group may be, for example, 100 to 1000; however, from the viewpoints of the fluidity of the resin composition and the dielectric characteristics of the cured product, the number average molecular weight (Mn) is preferably 150 to 500, more preferably 200 to 400, even more preferably 250 to 350, and particularly preferably 250 to 300.

The above-mentioned Mw and Mn mean values determined by gel permeation chromatography (GPC) and calculated relative to polystyrene standards.

The epoxy equivalent of the (B) compound having an epoxy group may be, for example, 200 to 330 g/eq; however, from the viewpoints of the fluidity of the resin composition and the dielectric characteristics of the cured product, the epoxy equivalent may be 220 to 310 g/eq, 220 to 290 g/eq, 220 to 270 g/eq, or 230 to 260 g/eq.

The curable resin composition may contain another component having a polymerizable functional group other than the (B) compound having an epoxy group, to the extent that does not significantly impair the effects of the present disclosure. From the viewpoint of further reducing the dielectric loss tangent of the cured product, it is preferable that the content of the other component having a polymerizable functional group is less than 10 parts by mass with respect to 100 parts by mass of the (B) compound having an epoxy group.

### <(C) Curing Agent>

The curing agent is a compound that itself participates in a curing reaction. Examples of the curing agent include an ester-based curing agent and a phenol-based curing agent. An ester-based curing agent can reduce the dielectric loss tangent of the cured product while improving the heat resistance of the cured product.

The ester-based curing agent is not particularly limited; however, from the viewpoint of further obtaining an effect of improving heat resistance and an effect of reducing the dielectric loss tangent, a compound having one or two or more ester groups having high reaction activity in one molecule, such as a phenol ester, an ester containing a dicyclopentadiene structure, an ester containing a naphthalene structure, a thiophenol ester, an N-hydroxyamine ester, or an ester of a heterocyclic hydroxy compound, is preferably used. As the ester-based curing agent, a compound containing a naphthalene structure may be used. Examples of the ester-based curing agent include “EPICLON HPC8000-65T”, “EPICLON HPC8000-L-65MT”, “EPICLON HPC8150-60T”, “EPICLON HPC8150-62T”, and “EPICLON HPC8150-65T” (all trade names manufactured by DIC Corporation). These can be used singly or in combination of two or more kinds thereof.

Examples of the phenol-based curing agent include, but are not particularly limited to, an alkylphenol resin, a phenol novolac resin, and a resin having a terminal phenolic hydroxyl group. From the viewpoint of further obtaining an effect of improving the heat resistance of a cured product of the curable resin composition, the phenol-based curing agent may be, for example, an alkylphenol resin or a phenol novolac resin, and may be an alkylphenol resin. From the viewpoint of further obtaining an effect of improving the heat resistance of a cured product of the curable resin composition and an effect of improving the adhesiveness of the cured product, the phenol-based curing agent may be, for example, a resin having a terminal phenolic hydroxyl group. The phenol-based curing agent is available as, for example, “PR1501” (trade name manufactured by Resonac Corporation) or “FTC509” (trade name manufactured by Gunei Chemical Industry Co., Ltd.). These can be used singly or in combination of two or more kinds thereof.

In the curable resin composition, the total content of the (B) compound having an epoxy group and the (C) curing agent may be 5% to 50% by mass, 10% to 45% by mass, or 15% to 40% by mass, based on the total amount of the (A) rubber component, the (B) compound having an epoxy group, and the (C) curing agent. When the total content of the (B) compound having an epoxy group and the (C) curing agent is 5% by mass or more, more sufficient curing is likely to be achieved, and at the same time, the cured product tends to have particularly excellent characteristics in terms of adhesiveness, insulation reliability, and heat resistance. When the total content of the (B) compound having an epoxy group and the (C) curing agent is 50% by mass or less, more sufficient elasticity is likely to be obtained, and the (B) compound having an epoxy group and the (C) curing agent tend to mix thoroughly with the rubber component.

### <(D) Curing Accelerator>

The (D) curing accelerator is a compound that functions as a catalyst for a curing reaction. The (D) curing accelerator may be selected from a tertiary amine, an imidazole, an organic acid metal salt, a phosphorus-based compound, a Lewis acid, an amine complex salt, and a phosphine. Among these, an imidazole may be used from the viewpoints of the storage stability and curability of a varnish of the curable resin composition and the dielectric characteristics of the cured product. When the (A) rubber component includes a rubber that is partially modified with maleic anhydride, an imidazole compatible with this may be selected. The imidazole may be 1-benzyl-2-methylimidazole.

In the curable resin composition, the content of the (D) curing accelerator may be 0.1 to 10 parts by mass with respect to 100 parts by mass of the total amount of the (A) rubber component, the (B) compound having an epoxy group, and the (C) curing agent. When the content of the (D) curing accelerator is 0.1 parts by mass or more, more sufficient curing tends to be easily achieved. When the content of the (D) curing accelerator is 10 parts by mass or less, the storage stability of a varnish, a film, and the like of the curable resin composition, and the heat resistance and dielectric characteristics of the cured product tend to be improved. From the above-described viewpoints, the content of the (D) curing accelerator may be 0.1 to 7 parts by mass, 0.2 to 5 parts by mass, or 0.3 to 3 parts by mass.

### <(E) Filler>

When the curable resin composition contains the (E) filler, there is a tendency that the linear expansion coefficient (CTE) of the cured product can be reduced.

The (E) filler may be a filler having at least one group selected from the group consisting of a (meth)acryloyl group, a vinyl group, an epoxy group, and a phenylamino group. By having these groups, the curable resin composition tends to have particularly excellent characteristics in terms of the compatibility with the resin component at the filler interface, the dispersibility of the filler, the storage stability of the curable resin composition, the linear expansion coefficient of the cured product, and the adhesiveness of the cured product. Therefore, the curable resin composition can be more suitably used as an interlayer adhesive for a multilayer printed wiring board.

From the viewpoints of the linear expansion coefficient and the adhesiveness, it is preferable that the (E) filler includes a filler having at least one group selected from the group consisting of a (meth)acryloyl group, a vinyl group, an epoxy group, and a phenylamino group; it is more preferable that the (E) filler includes a filler having at least one group selected from the group consisting of a vinyl group, an epoxy group, and a phenylamino group; and it is even more preferable that the (E) filler includes a filler having an epoxy group.

As the (E) filler, from the viewpoints of the linear expansion coefficient and the adhesiveness to a resin substrate with low polarity, a filler having a vinyl group or an epoxy group is more preferred, and from the same viewpoints, a filler having an epoxy group is particularly preferred. Examples of the resin substrate with low polarity include a liquid crystal polymer.

The (E) filler may be a filler that has been subjected to a surface treatment. A surface-treated filler can be obtained by treating the surface of a filler with a surface treatment agent such as an organosilane compound. By treating the surface of the filler, the compatibility with the resin component at the filler interface, the curable resin composition tends to have particularly excellent characteristics in terms of the dispersibility of the filler, the storage stability of the curable resin composition, the linear expansion coefficient of the cured product, and the adhesiveness of the cured product. Therefore, when a filler that has been subjected to a surface treatment is used as the (E) filler, the curable resin composition can be more suitably used as an interlayer adhesiveness for a multilayer printed wiring board. The surface treatment may be surface modification.

From the viewpoints of the linear expansion coefficient and adhesiveness, it is preferable that the surface-treated filler includes a filler having at least one group selected from the group consisting of a (meth)acryloyl group, a vinyl group, an epoxy group, and a phenylamino group; it is more preferable that the surface-treated filler includes a filler having at least one group selected from the group consisting of a vinyl group, an epoxy group, and a phenylamino group; and a filler having an epoxy group is even more preferred.

As the surface-treated filler, from the viewpoints of the linear expansion coefficient and the adhesiveness to a resin substrate with low polarity, a filler having a vinyl group or an epoxy group is even more preferred, and from the same viewpoints, a filler having an epoxy group is particularly preferred. Examples of the resin substrate with low polarity include a liquid crystal polymer.

When the above-mentioned surface-treated filler is used, the cured product of the curable resin composition tends to have further improved adhesiveness to the materials constituting a printed wiring board and the like and tends in particular to have further improved adhesiveness to a substrate having a low-roughened or non-roughened surface. A cured product of the curable resin composition containing the above-mentioned surface-treated filler tends to obtain satisfactory adhesiveness to a resin substrate with low polarity, for example, a non-roughened liquid crystal polymer film.

From the viewpoint of achieving both the fluidity of the curable resin composition and the reduction of the linear expansion coefficient of the cured product, the content of the (E) filler may be 30% to 75% by mass, 30% to 70% by mass, 40% to 70% by mass, or 50% to 65% by mass, based on the total amount of solid content of the curable resin composition. When the content of the (E) filler is within the above-described range, both the fluidity of the curable resin composition and the reduction of the linear expansion coefficient of the cured product can be achieved.

From the viewpoint of achieving excellent dielectric characteristics, adhesiveness, and film appearance of the cured product, the average particle size of the (E) filler may be 0.01 μm or more, 0.1 μm or more, or 0.2 μm or more, and may be 5.0 μm or less, 4.0 μm or less, 3.0 μm or less, 1.0 μm or less, or 0.8 μm or less. The average particle size of the (E) filler means the particle size at a cumulative frequency of 50% in the particle size distribution determined by a laser diffraction and scattering method.

As the (E) filler, from the viewpoint of further reducing the linear expansion coefficient and improving the elastic modulus, an inorganic filler may be used. Examples of the inorganic filler include fillers containing at least one inorganic substance selected from the group consisting of silica, alumina, titania, tantalum oxide, zirconia, silicon nitride, gallium oxide, boron nitride, barium titanate, barium carbonate, magnesium carbonate, aluminum hydroxide, magnesium hydroxide, lead titanate, lead zirconate titanate, lead lanthanum zirconate titanate, spinel, mullite, cordierite, talc, aluminum titanate, yttria-containing zirconia, barium sulfate, barium silicate, calcium carbonate, calcium sulfate, zinc oxide, and magnesium titanate. The inorganic filler may be used singly or in combination of two or more kinds thereof. Among these, from the viewpoint of the dispersibility and the curability of the cured product, the inorganic filler may be an inorganic filler containing any of silica, alumina, titania, and boron nitride. From the viewpoint of dielectric characteristics, the inorganic filler may be an inorganic filler containing silica.

As the (E) filler, an organic filler may be used. Examples of the organic filler include fillers formed from liquid crystal polymers (LCP) and polytetrafluoroethylene (PTFE). The organic filler may be used singly or in combination of two or more kinds thereof. Furthermore, regarding the (E) filler, one kind or two or more kinds of inorganic fillers and one kind or two or more kinds of organic fillers may be used in combination.

From the viewpoints of dispersibility and heat resistance, the (E) filler may be an inorganic filler obtained by surface-treating silica, alumina, titania, or boron nitride, or may be an inorganic filler obtained by surface-treating silica, alumina, or boron nitride. From the viewpoints of the linear expansion coefficient and adhesiveness, the (E) filler may be a surface-treated silica filler obtained by surface-treating silica.

As the surface treatment agent for the inorganic filler, from the viewpoints of the linear expansion coefficient and adhesiveness, an organosilane compound such as an epoxysilane compound, an aminosilane compound, a (meth)acrylsilane compound, or a vinylsilane compound may be used.

Examples of the organosilane compound include 3-aminopropyltrimethoxysilane, 3-aminopropyltriethoxysilane, 3-(2-aminoethyl)aminopropyltrimethoxysilane, 3-(2-aminoethyl)aminopropylmethyldimethoxysilane, 3-phenylaminopropyltrimethoxysilane, 3-glycidoxypropyltrimethoxysilane, 3-glycidoxypropylmethyldimethoxysilane, 3-glycidoxypropyltriethoxysilane, 3-glycidoxypropylmethyldiethoxysilane, vinyltriacetoxysilane, vinyltrimethoxysilane, vinyltriethoxysilane, vinyltriisopropoxysilane, allyltrimethoxysilane, diallyldimethylsilane, 3-methacryloxypropyltrimethoxysilane, 3-methacryloxypropylmethyldimethoxysilane, 3-methacryloxypropyltriethoxysilane, 3-mercaptopropyltrimethoxysilane, 3-mercaptopropylmethyldimethoxysilane, 3-mercaptopropyltriethoxysilane, N-(1,3-dimethylbutylidene)-3-aminopropyltriethoxysilane, 2-(3,4-epoxycyclohexyl)ethyltrimethoxysilane, tris(trimethoxysilylpropyl) isocyanurate, and 3-isocyanatopropyltriethoxysilane.

### <Other Components>

The curable resin composition may further contain, in addition to the above-mentioned components, an antioxidant, an anti-yellowing agent, an ultraviolet absorber, a visible light absorber, a colorant, a plasticizer, a stabilizer, a filler, a flame retardant, a leveling agent, and the like as necessary, to the extent that does not significantly impair the effects of the present disclosure.

In particular, the curable resin composition may contain at least one deterioration inhibitor selected from the group consisting of an antioxidant, a thermal stabilizer, a light stabilizer, and a hydrolysis inhibitor. The antioxidant suppresses deterioration caused by oxidation. Furthermore, the antioxidant imparts sufficient heat resistance at high temperatures to the cured product. The thermal stabilizer imparts stability at high temperatures to the cured product. Examples of the light stabilizer include an ultraviolet absorber that prevents deterioration caused by ultraviolet deterioration, a light blocking agent that blocks light, and a quencher having a quenching function that accepts the light energy absorbed by an organic material and stabilizes the organic material. The hydrolysis inhibitor suppresses deterioration caused by moisture. The deterioration inhibitor may be at least one selected from the group consisting of an antioxidant, a thermal stabilizer, and an ultraviolet absorber. As the deterioration inhibitor, only one kind of the components mentioned above as examples may be used, or two or more kinds thereof may be used in combination. In order to obtain more excellent effects, two or more kinds of deterioration inhibitors may be used in combination.

The curable resin composition may be prepared as a resin varnish in which each of the above-mentioned components is dissolved or dispersed in an organic solvent. The organic solvent is not particularly limited; however, examples thereof include aromatic hydrocarbons such as toluene, xylene, mesitylene, cumene, and p-cymene; cyclic ethers such as tetrahydrofuran and 1,4-dioxane; ketones such as acetone, methyl ethyl ketone (MEK), methyl isobutyl ketone (MIBK), cyclohexanone, and 4-hydroxy-4-methyl-2-pentanone; esters such as methyl acetate, ethyl acetate, butyl acetate, methyl lactate, ethyl lactate, and γ-butyrolactone; carbonic acid esters such as ethylene carbonate and propylene carbonate; and amides such as N,N-dimethylformamide, N,N-dimethylacetamide, and N-methyl-2-pyrrolidone. From the viewpoints of solubility and boiling point, toluene or N,N-dimethylacetamide may be used. These organic solvents can be used singly or in combination of two or more kinds thereof. The concentration of the solid content (components other than the organic solvent) in the resin varnish may be 20% to 80% by mass.

Mixing and kneading of the above-described resin varnish can be carried out by appropriately combining conventional dispersing machines such as a stirrer, a kneader, a three-roll, and a ball mill.

### [Curable Film and Layered Film]

A curable film according to the present embodiment is formed from the above-mentioned curable resin composition. The curable film can be easily produced by, for example, applying a resin varnish containing the curable resin composition on a substrate film and removing the solvent from the coating film. According to this method, a layered film including a substrate film and a curable film provided on the substrate film can be obtained.

From the coating film on the substrate film, the solvent is removed by drying at a temperature such that the curable resin composition is not cured and under the conditions in which the solvent volatilizes sufficiently. Specifically, the coating film is usually dried by heating the coating film at 60° C. to 180° C. for 0.1 to 90 minutes. The preferred residual volatile content of the resulting curable film is 10% by mass or less. When this residual volatile content is 10% by mass or less, it is easy to suppress voids from remaining inside the cured product due to foaming caused by solvent volatilization during assembling and heating. Furthermore, contamination of surrounding materials or members by volatile components generated during heating can be easily suppressed.

The material for the substrate film is not particularly limited, and examples thereof include polyesters such as polyethylene terephthalate (PET), polybutylene terephthalate, and polyethylene naphthalate; polyolefins such as polyethylene and polypropylene; polycarbonate, polyamide, polyimide, polyamideimide, polyether imide, polyether sulfide, polyether sulfone, polyether ketone, polyphenylene ether, polyphenylene sulfide, polyarylate, polysulfone, and liquid crystal polymers. Among these, from the viewpoints of flexibility and toughness, polyethylene terephthalate, polybutylene terephthalate, polyethylene naphthalate, polypropylene, polycarbonate, polyamide, polyimide, polyamideimide, polyphenylene ether, polyphenylene sulfide, polyarylate, or polysulfone is preferred.

The thickness of the substrate film may be appropriately varied depending on the intended flexibility; however, the thickness may be 3 to 250 μm. In general, when the thickness is 3 μm or more, the film strength is sufficient, and when the thickness is 250 μm or less, sufficient flexibility is obtained. From the above-described viewpoint, the thickness may be 5 to 200 μm, 7 to 150 μm, or 10 to 100 μm. From the viewpoint of improving the peelability from the curable film, a substrate that has been subjected to a release treatment using a silicone-based compound, a fluorine-containing compound, or the like may be used as necessary.

If necessary, the protective film may be stuck onto the curable film to form as a layered film having a three-layer structure composed of a substrate film, a curable film, and a protective film.

The material for the protective film is not particularly limited, and examples thereof include polyesters such as polyethylene terephthalate, polybutylene terephthalate, and polyethylene naphthalate; and polyolefins such as polyethylene and polypropylene. Among these, from the viewpoints of flexibility and toughness, polyesters such as polyethylene terephthalate; and polyolefins such as polyethylene and polypropylene are preferred. From the viewpoint of improving the peelability from the curable film, a protective film that has been subjected to a release treatment using a silicone-based compound, a fluorine-containing compound, or the like may be used as necessary.

The thickness of the protective film may be appropriately varied depending on the intended flexibility; however, the thickness may be 10 to 250 μm. In general, when the thickness is 10 μm or more, the film strength is sufficient, and when the thickness is 250 μm or less, sufficient flexibility is obtained. From the above-described viewpoints, the thickness of the protective film may be 10 to 200 μm, 15 to 150 μm, or 20 to 100 μm.

The thickness after drying of the curable film is not particularly limited; however, the thickness may be usually 5 to 1000 μm. When the thickness is 5 μm or more, the curable film or a cured product thereof tends to easily obtain sufficient strength. When the thickness is 1000 μm or less, drying can be sufficiently carried out, and therefore, the amount of residual solvent in the curable film tends to be easily reduced.

The layered film can be easily stored by, for example, being wound up in a roll form. Alternatively, a sheet-shaped layered film cut from a roll-shaped film into a suitable size may be stored.

The curable resin composition, curable film, and layered film according to the present embodiment are suitable for forming a protective layer (coverlay) that covers an electric circuit on a printed wiring board and as an interlayer adhesive in a multilayer printed wiring board, and are particularly suitable as an interlayer adhesive.

### [Printed Wiring Board]

A printed wiring board according to the present embodiment includes a layered body formed of a metal part that forms an electric circuit (conductor circuit) and a resin substrate, as a constituent element. The printed wiring board can be produced by, for example, a conventionally known method such as a subtractive method using a metal-clad layered body. The printed wiring board according to the present embodiment is a general term for so-called flexible circuit boards (FPC), flat cables, circuit boards for tape automated bonding (TAB), and the like, in which a conductor circuit formed by metal parts is partially or completely covered using a coverlay film, screen printing ink, or the like as necessary.

The printed wiring board of the present embodiment can have any layered configuration that can be employed as a printed wiring board. For example, the printed wiring board can be produced as a printed wiring board having a substrate layer, an adhesive layer, a metal part, and a protective layer.

In addition, if necessary, a multilayer printed wiring board may be configured, in which two or three or more of the above-described printed wiring boards are stacked using an interlayer adhesive.

In the printed wiring board of the present embodiment, any substrate that has been conventionally used as a substrate for printed wiring boards can be used as the substrate layer.

In the printed wiring board of the present embodiment, any resin that has been conventionally used as a substrate for printed wiring boards can be used as the substrate layer. Examples of the resin of the substrate layer include a polyester resin, a polyamide resin, a polyimide resin, a polyamideimide resin, a liquid crystal polymer, polyphenylene sulfide, syndiotactic polystyrene, a polyolefin-based resin, and fluororesins (PTFE and the like) such as polytetrafluoroethylene (PTFE).

It is possible to use the curable resin composition of the present embodiment for each adhesive layer, protective layer, or interlayer adhesive of a printed wiring board. Particularly, when these layers are formed using the curable resin composition of the present embodiment, the embedding properties and formability are excellent, and layers themselves formed using the curable resin composition have excellent low dielectric characteristics and can realize a low linear expansion coefficient. A cured product of the curable resin composition of the present embodiment tends to have excellent adhesiveness to, for example, the materials constituting a printed wiring board, such as a substrate layer and a metal part, in particular, even to substrates with low polarity such as a liquid crystal polymer, polyphenylene sulfide, syndiotactic polystyrene, a polyolefin-based resin, and PTFE. Therefore, the curable resin composition of the present embodiment is suitable as an interlayer adhesive for a multilayer printed wiring board. Furthermore, the curable resin composition of the present embodiment is also suitable as a curable resin composition used for a coverlay film, a layered board, resin-coated copper foil, and a bonding sheet. Furthermore, since the curable resin composition according to the present embodiment contains the (A) rubber component, a cured product thereof can have flexibility. Therefore, the curable resin composition according to the present embodiment can be suitably used for forming a protective layer and as an interlayer adhesive for flexible printed wiring boards.

In the printed wiring board of the present embodiment, the metal part is not particularly limited; however, from the viewpoint of wiring formability, the metal part may be copper. The material that forms the copper is not particularly limited, and for example, electrolytic copper foil and rolled copper foil used in copper-clad layered boards and printed wiring boards can be used. Examples of commercially available electrolytic copper foil include F0-WS-18 (manufactured by Furukawa Electric Co., Ltd., trade name), NC-WS-20 (manufactured by Furukawa Electric Co., Ltd., trade name), YGP-12 (manufactured by Nippon Denkai, Ltd., trade name), GTS-18 (manufactured by Furukawa Electric Co., Ltd., trade name), F2-WS-12 (manufactured by Furukawa Electric Co., Ltd., trade name), and F2-WS-18 (manufactured by Furukawa Electric Co., Ltd., trade name). Examples of rolled copper foil include TPC foil (manufactured by JX Advanced Metals Corporation, trade name), HA foil (manufactured by JX Advanced Metals Corporation, trade name), HA-V2 foil (manufactured by JX Advanced Metals Corporation, trade name), and C1100R (manufactured by Mitsui Sumitomo Metal Mining Brass & Copper Co., Ltd., trade name). From the viewpoint of the adhesiveness to the cured product of the curable resin composition of the present embodiment, copper foil that has been subjected to a roughening treatment may be used. From the viewpoint of folding resistance, rolled copper foil may be used. Furthermore, the metal part may have a roughened surface formed by a roughening treatment.

### EXAMPLES

The present disclosure will be more specifically described by way of the following Examples. However, the present disclosure is not intended to be limited to these Examples.

### Curable Resin Composition

### Examples 1 to 4 and Comparative Examples 1 to 3

Each material shown in Table 1 was mixed at the solid content proportion (unit: parts by mass) shown in the same table, and a curable resin composition was prepared. The curable resin composition was prepared by adding toluene as a solvent so as to obtain a solid content of 40% by mass. The details of each material will be described below.

### (A) Rubber Component

Unmodified styrene-based elastomer: SEBS elastomer (Kraton Polymers Japan, Ltd., trade name “KRATON MD1653 MO”, Mw: 65000, modification of maleic anhydride: none)
Modified styrene-based elastomer (A1): Maleic anhydride-modified SEBS elastomer (Synthesis Example 1, Mw: 69000, modification ratio of maleic anhydride: 2.1% by mass)
Modified styrene-based elastomer (A2): Maleic anhydride-modified SEBS elastomer (Kraton Polymers Japan, Ltd., trade name “KRATON FG1924GT”, Mw: 127000, modification ratio of maleic anhydride: 1.0% by mass)

### Synthesis Example 1

950 g of xylene, 100 g of a hydrogenated styrene-based thermoplastic elastomer (Kraton Polymers Japan, Ltd., trade name “KRATON MD1653 MO”), and 17.0 g of maleic anhydride (FUJIFILM Wako Pure Chemical Corporation) were introduced into a 2-L flask equipped with a cooling tube, a nitrogen inlet tube, a thermocouple, and a stirrer, the mixture was stirred at 80° C. for 0.5 hours, and then nitrogen bubbling was performed at a flow rate of 0.5 cm³/L for 1.0 hour. Next, 6.5 g of benzoyl peroxide (FUJIFILM Wako Pure Chemical Corporation) was added thereto, the mixture was stirred for 6.0 hours while nitrogen bubbling was performed at 80° C., and a reaction was carried out. Unreacted maleic anhydride was extracted three times from the reaction liquid using isopropyl alcohol, and the extract liquid was concentrated. The concentrate was dried in a vacuum at 70° C., and a modified styrene-based elastomer having a succinic anhydride group (maleic anhydride-modified SEBS elastomer) was obtained.

### (Acid Value)

0.5 mL of distilled water was added to a liquid obtained by mixing about 1 g of the modified styrene-based elastomer (A1) and 200 g of xylene at 80° C., subsequently the mixture was stirred at the reflux temperature for 1 hour, and succinic anhydride groups were hydrolyzed. The mixed liquid was cooled to 80° C., a small amount of phenolphthalein was added thereto, and then a 0.1 M potassium hydroxide (KOH)-containing ethanol solution was added dropwise thereto until the color did not disappear for 30 seconds. The acid value (mg KOH/g) was measured from the amount of the modified styrene-based elastomer and the amount of KOH added dropwise. The acid value of the modified styrene-based elastomer is a value derived from two carboxy groups produced by hydrolysis of succinic anhydride groups.

### (Modification Ratio)

The modification ratio of maleic anhydride of the modified styrene-based elastomer (A1) was calculated by introducing the acid value, the molecular weight of KOH, and the molecular weight of maleic anhydride into the following formula.

$$Modification ratio ( \% by mass ) = [ Acid value ( mg KOH / g ) / molecular weight of KOH ( mg / mol ) ] \times 0.5 \times molecular weight of maleic anhydride ( g / mol ) \times 100 ( \% )$$

### (B) Compound Having Epoxy Group

HP7200L: Dicyclopentadiene type epoxy resin (manufactured by DIC Corporation, trade name “EPICLON HP-7200L”, epoxy equivalent: 247 g/eq, Mn: 288, Mw: 401)

### (C) Curing Agent

HPC8150-62T: Ester-based curing agent (manufactured by DIC Corporation, trade name “EPICLON HPC8150-62T”, an active ester compound containing a naphthalene structure, a toluene solution having a solid content of 62% by mass)

### (D) Curing Accelerator

1B2MZ: 1-Benzyl-2-methylimidazole (manufactured by Shikoku Chemicals Corporation, trade name “1B2MZ”)

### (E) Filler

SC2050-MB: Epoxy group-modified silica filler dispersion (manufactured by Admatechs Co., Ltd., trade name “SC2050-MB”, average particle size: 0.50 μm, solvent: MEK, solid content: 70% by mass)

### [Layered Film A]

As a substrate film, a release-treated polyethylene terephthalate (PET) film (manufactured by Toyobo Co., Ltd., trade name “PUREX A3100”, thickness 25 μm) was prepared. The above-described curable resin composition was applied on the release-treated surface of this PET film using a knife coater (manufactured by Yasui Seiki, Inc., trade name “SNC-350”). The coating film was dried by heating at 80° C. for 15 minutes in a dryer (manufactured by Futaba Kagaku Co., Ltd., trade name “MSO-80TPS”) to form a curable film having a thickness of 30 μm. The same release-treated PET film as the substrate film was stuck to the formed curable film as a protective film in a direction such that the release-treated surface was on the curable film side, to obtain a layered film A. Incidentally, the curable resin composition of Comparative Example 2 separated, and a layered film A could not be produced.

### (Melt Viscosity)

The substrate film and the protective film were removed from the layered film A to leave only the curable film, and the lowest melt viscosity of this curable film was measured using a viscoelasticity measuring apparatus (manufactured by TA Instruments, Inc., trade name “ARES-G2”, temperature increase rate: 3° C./min, temperature range: 30° C. to 200° C., load: 0.2 N, frequency: 1 Hz, strain: 1%).

### (Adhesiveness)

The protective film of the layered film A was peeled, and an electrolytic copper foil (manufactured by Furukawa Electric Co., Ltd., trade name “F2-WS-18”, thickness 18 μm) having a roughened surface with a surface roughness Rz of 1.8 μm (hereinafter, also referred to as “VLP-Cu foil”) was stacked on the exposed curable film. At this time, the VLP-Cu foil was stacked on the curable film in a direction such that the roughened surface was on the curable film side. In that state, the VLP-Cu foil was laminated on the curable film using a vacuum pressure laminator (manufactured by Nikko-Materials Co., Ltd., trade name “V130”) under the conditions of a pressure of 0.5 MPa, a temperature of 100° C., and a pressing time of 1 minute. Next, the substrate film was peeled, VLP-Cu foil was stacked on the exposed curable film in a direction such that the roughened surface was on the curable film side, and then the VLP-Cu foil was laminated on the curable film under the above-described conditions. Thereafter, a layered body having VLP-Cu foil, a cured film that was a cured product of the curable film, and VLP-Cu foil was obtained by heating the assembly in a dryer (manufactured by Futaba Kagaku Co., Ltd., trade name “MSO-80TPS”) at 180° C. for 60 minutes.

A sample for measuring peel strength having a size of 100 mm in length and 5 mm in width was cut out from the obtained layered body. One of the VLP-Cu foil surfaces of this sample was fixed to a glass plate using an epoxy adhesive (manufactured by Huntsman Japan K.K., trade name “ARALDITE RAPID”). A 90-degree peel test was carried out, in which the other VLP-Cu foil and the cured film were gripped with jigs using an autograph (manufactured by Shimadzu Corporation, trade name “EZ-LX”) under the conditions of a tensile rate of 50 mm/min, and the cured film was peeled from the VLP-Cu foil fixed to the glass plate.

### [Layered Film B]

As a substrate film, a release-treated polyethylene terephthalate (PET) film (manufactured by Toyobo Co., Ltd., trade name “PUREX A3100”, thickness 25 μm) was prepared. The above-described curable resin composition was applied on the release-treated surface of this PET film using a knife coater (manufactured by Yasui Seiki, Inc., trade name “SNC-350”). The coating film was dried by heating at 80° C. for 15 minutes in a dryer (manufactured by Futaba Kagaku Co., Ltd., trade name “MSO-80TPS”) to form a curable film having a thickness of 25 μm. The same release-treated PET film as the substrate film was stuck to the formed curable film as a protective film in a direction such that the release-treated surface was on the curable film side, to obtain a layered film B. Incidentally, the curable resin composition of Comparative Example 2 separated, and a layered film B could not be produced.

### (Embedding Properties)

A substrate was prepared in which a copper foil having a dot-shaped etched pattern having a residual copper ratio of 90%, a thickness of 12 μm, and a diameter of 0.26 mm was layered on one surface, and a lattice-shaped etched pattern having a residual copper ratio of 20%, a thickness of 12 μm, and a width of 0.15 mm was layered on the other surface. The protective film of the layered film B was peeled, the exposed curable film was stacked on both surfaces of the above-described substrate, and then the assembly was laminated using a vacuum pressure laminator (V130) under the conditions of a pressure of 0.5 MPa, a temperature of 100° C., and a pressing time of 1 minute. Next, a double-sided copper-clad layered body was produced by peeling the substrate film, further stacking VLP-Cu foil (manufactured by Furukawa Electric Co., Ltd., trade name “F2-WS-18”, thickness: 18 μm) on both surfaces of the curable film, and pressing the assembly using a small-sized vacuum press machine (manufactured by Imoto Machinery Co., Ltd., trade name “IMC-18EE-A”). Regarding the pressing conditions, a pressure of 3 MPa was applied, the temperature was raised from 30° C. to 180° C. at 3° C./min in a vacuum, and the temperature was maintained at 180° C. for 60 minutes. The double-sided copper-clad layered body was subjected to a reflow step at 260° C. three times, and a case in which no peeling or lifting occurred on the surface was rated as “OK”, while a case in which peeling or lifting occurred was rated as “NG”.

TABLE 1

| | | Example | | | | Comparative Example | | |
|---|---|---|---|---|---|---|---|---|
| | | 1 | 2 | 3 | 4 | 1 | 2 | 3 |
| (A) | Modified styrene- | 30 | 30 | 80 | 65 | — | — | — |
| | based elastomer (A1) | | | | | | | |
| | Modified styrene- | 50 | 35 | — | — | 80 | 65 | 50 |
| | based elastomer (A2) | | | | | | | |
| | Unmodified styrene- | — | — | — | — | — | — | 30 |
| | based elastomer | | | | | | | |
| (B) | HP7200L | 10.4 | 18.1 | 10.4 | 18.1 | 10.4 | 18.1 | 10.4 |
| (C) | HPC8150-62T | 9.6 | 16.9 | 9.6 | 16.9 | 9.6 | 16.9 | 9.6 |
| (D) | 1B2MZ | 0.5 | 0.5 | 0.5 | 0.5 | 0.5 | 0.5 | 0.5 |
| (E) | SC2050-MB | 150 | 150 | 150 | 150 | 150 | 150 | 150 |
| Content | % by mass | 60 | 60 | 60 | 60 | 60 | 60 | 60 |
| of filler | % by volume | 40 | 40 | 40 | 40 | 40 | 40 | 40 |

| | | | | | | | |
|---|---|---|---|---|---|---|---|
| Lowest melt viscosity (Pa · s) | 18010 | 28830 | 42090 | 22530 | 19930 | — | 9390 |
| Peel strength (kN/m) | 2.4 | 1.6 | 0.9 | 0.7 | 4.2 | — | 3.5 |
| Embedding properties | OK | OK | OK | OK | NG | — | NG |

1. A curable resin composition comprising:
(A) a rubber component;
(B) a compound having an epoxy group;
(C) a curing agent;
(D) a curing accelerator; and
(E) a filler,
wherein the (A) rubber component includes a modified styrene-based elastomer having a modification ratio of maleic anhydride of 1.8% to 10.0% by mass.

2. The curable resin composition according to claim 1, wherein the curable resin composition is used as an interlayer adhesive for a multilayer printed wiring board.

3. The curable resin composition according to claim 1, wherein the modified styrene-based elastomer has a weight average molecular weight of 20000 to 120000.

4. The curable resin composition according to claim 1, wherein the (B) compound having an epoxy group has a weight average molecular weight of 200 to 1000.

5. The curable resin composition according to claim 1, wherein a content of the (D) curing accelerator is 0.1 to 10 parts by mass with respect to 100 parts by mass of a total amount of the (A) rubber component, the (B) compound having an epoxy group, and the (C) curing agent.

6. The curable resin composition according to claim 1, wherein the (E) filler includes a surface-treated filler.

7. The curable resin composition according to claim 6, wherein the surface-treated filler includes a filler having at least one group selected from the group consisting of an epoxy group, a vinyl group, and a phenylamino group.

8. A curable film comprising the curable resin composition according to claim 1.

9. A layered film comprising:
a substrate film; and
the curable film according to claim 8 provided on the substrate film.
